(19) United States
(12) Patent Application Publication
(10) Pub. No.: US 2013/0221962 A1
(43) Pub. Date: Aug. 29, 2013

(54) METHOD FOR DETERMINING AN ACTIVATION SEQUENCE FOR A MAGNETIC RESONANCE DEVICE

(71) Applicants: Hans-Peter Fautz, Forchheim (DE); Rene Gumbrecht, Herzogenaurach (DE)

(72) Inventors: Hans-Peter Fautz, Forchheim (DE); Rene Gumbrecht, Herzogenaurach (DE)

(73) Assignee: Siemens Aktiengesellschaft, Munchen (DE)

(21) Appl. No.: 13/593,322

(22) Filed: Aug. 23, 2012

(30) Foreign Application Priority Data
Aug. 24, 2011 (DE) 10 2011 081 509.0

(51) Int. Cl. G01R 33/44

(52) U.S. Cl. CPC G01R 33/44
USPC 324/309; 324/318

(57) ABSTRACT

A method for determining an activation sequence for a magnetic resonance device is provided. The activation sequence includes single pulses to be emitted simultaneously for a plurality of individually activatable high-frequency transmission channels. The method includes determining an amplitude and a phase of a plurality of square-wave subpulses, of which the single pulse is composed, by a pulse optimization method for a predefined target magnetization for each of the single pulses. The method also includes determining optimized, layer-selective subpulses for each square-wave subpulse of the plurality of square-wave subpulses while retaining phase and integral of the square-wave subpulse with regard to a bandwidth of the plurality of square-wave subpulses and/or the quality of a profile of a layer to be excited.

This application claims the benefit of DE 10 2011 081 509.0, filed on Aug. 24, 2011.

### BACKGROUND

The present embodiments relate to a method for determining an activation sequence for a magnetic resonance device.

Magnetic resonance has long been known as an imaging method. An object to be examined is introduced into a relatively high basic magnetic field (e.g., the B₀ field). To be able to record magnetic resonance data (e.g., in a layer), the spins of the layer are excited, and the decay, for example, of this excitation is observed as a signal. Gradient fields may be generated using a gradient coil assembly, while high frequency excitation signals (e.g., high frequency pulses) may be emitted via a high-frequency transmission coil. A high frequency field (e.g., B₁) is generated by the high frequency pulses, and the spins of resonantly excited nuclei are spatially resolved by the gradients, and tilted about a flip angle with respect to the magnetic field lines of the basic magnetic field.

If the spins of the nuclei relax again, high-frequency signals are emitted, and the high-frequency signals are received by suitable receiving antenna and are processed further to thus reconstruct magnetic resonance image data.

High-frequency transmission coils are operated in a “homogeneous mode” (e.g., a “CP-mode”), where a single high frequency pulse with a defined fixed phase and amplitude is given on all components of the transmission coil (e.g., all transmission rods of a birdcage antenna). Parallel transmission, in which a plurality of transmission channels are each loaded with single pulses that may differ from each other, may be enabled. This totality of single pulses is defined as a whole in an activation frequency. Such a multi-channel pulse, which is composed of single pulses for the different transmission channels, may be referred to as a “pTX-pulse” (for “parallel transmission”).

Calculation methods (e.g., optimization methods) are known for determining an activation frequency for a transmission device of a magnetic resonance device including a plurality of transmission channels. A target magnetization may be specified (e.g., a magnetic resonance excitation quality requirement). For example, a desired spatially resolved flip angle distribution that corresponds to a target magnetization may be indicated. A target function may accordingly be defined. A suitable activation sequence (e.g., the single pulses for the channels) is determined by the optimization method (e.g., the target function optimizer). Reference is made purely by way of example for such a method for determining activation sequences for parallel excitation methods to the article by W. Grissom et al., “Spatial Domain Method for the Design of RF pulse in Multicoil Parallel Excitation,” Mag. Res. Med. 56, 620-629, 2006.

Together with additional control requirements (e.g., the associated gradient pulses), the activation sequence forms the measurement report. The measurement report allows automatic control of the magnetic resonance device for a measurement.

In the earlier German patent application DE 10 2011 006 151.7, which is hereby incorporated by reference in its entirety, a method and a device for determining a magnetic resonance system activation sequence, in which a further reduction in the local high-frequency loading of the patient is enabled by an activation sequence with optimal adherence to an MR excitation quality requirement (e.g., target magnetization), are known. There, as already described in the cited article, a multi-channel pulse is calculated in an HF pulse-optimization method on the basis of an MR excitation quality requirement. In addition, a length (e.g., the duration of a pulse) is optimized in the HF pulse-optimization method with respect to an HF energy parameter, which, for example, may be a parameter that represents a local and/or global energy input into the object being examined or a local/global HF load value (e.g., an SAR or SED value) of an object being examined. For consideration, the target function may be expanded, for example, by a term that includes the HF energy parameter, and an additional parameter (e.g., the pulse length) may be used as a parameter to be optimized. Procedures, in which the pulse optimization method is carried out for a plurality of fixed pulse lengths, after which the result that leads to the lowest value for the HF energy parameter is used, are provided.

In the article “RF energy reduction by parallel transmission using large tip-angle composite pulses,” by R. Gumbrecht et al., Proc. Intl. Soc. Mag. Reson. Med. 19 (2011) 4443, a method for reducing the high-frequency energy by the use of composite pulses is described. Every single pulse for a transmission channel includes a plurality of subpulses that are suitable where B₁ inhomogeneities exist. Parallel transmission may be used to lengthen pulses and thus fulfill output or SAR limits, while the excitation performance (e.g., the target magnetization) is retained. A fast, non-linear optimizer that efficiently solves the Bloch equations is used. The single pulses are generated as non-layer-selective square-wave pulses that are divided into a plurality of subpulses having different amplitudes and phases as variable optimization parameters for each transmission channel.

Magnetic resonance imaging also makes high demands on the bandwidth of the high-frequency pulses used depending on the type of measurement. For example, broadband excitations are required if a layer selection takes place using layer selection gradients, if B₀ inhomogeneities exist over the imaging volume, if nuclei (e.g., protons) with different chemical shifts are to be excited (compare fat/water shift), and if spectroscopy is to be conducted. Broadband excitations use a high localization of the progression over time of the high-frequency pulses. The pulses are thus very narrow in the time domain. To attain a desired flip angle, the pulses therefore have a very high amplitude, resulting in high technical demands on the maximum output (peak output).

In this connection, the excited layer thickness depends on the bandwidth of the pulse to be used and the gradient amplitude of the layer selection gradient. Small gradients are thus used, so the demand on the bandwidth and the peak output of the high-frequency pulses is reduced. This, however, has the drawback that use of smaller gradient amplitudes leads to strong spatial miscodings or excitations of spins having a frequency shift owing to B₀ variations or chemical shift.

It has also been proposed, as already described by the cited article by R. Gumbrecht et al., that composite pulses, in which a single pulse is distributed among a plurality of layer-selective subpulses, are used. The desired flip angle is produced by this combination of subpulses. The demands on local and/or global SAR and the maximum output may be reduced in the process in that a plurality of subpulses are produced having an amplitude that is lower by a corresponding factor. To maintain the pulse length, the time-bandwidth product (TBW) of the subpulses is reduced accordingly. This, however, leads to a deterioration of the layer profile. The layer profile may be optimized considerably more easily for small flip angles (e.g., flip angles <90°) than for large flip angles, so an optimization of the layer profile adapted to the reduced flip angle of the subpulses may at least partially compensate these effects depending on the choice of the number of subpulses. The known procedures therefore barely provide any options with regard to improvement in relation to the bandwidth and/or the layer profile.

### SUMMARY AND DESCRIPTION

The present embodiments may obviate one or more of the drawbacks or limitations in the related art. For example, a method that improves the bandwidth of the pulses and/or the layer profile is provided.

In one embodiment, a method includes determining the amplitude and the phase of a plurality of square-wave subpulses, of which a single pulse is composed, by a pulse optimization method for a predefined target magnetization for each single pulse. The method also includes determining optimized, layer-selective subpulses for each square-wave pulse of the plurality of square-wave subpulses, while retaining phase and integral of the square-wave pulse with regard to the bandwidth of the subpulses and/or a quality of a profile of a layer to be excited.

According to one embodiment, square-wave subpulses of the single pulses that differ in amplitude and phase, respectively, are determined. The square-wave subpulses obtained, as a result, are not layer-selective. The integral ultimately describes a flip angle that the square-wave subpulses produce. By way of example, three square-wave subpulses may be determined for each single pulse. A method for the design of composite pulses for parallel transmission (e.g., the pulse optimization method) forms the basis. In this pulse optimization method, the desired insensitivity to B₀ and B₁ inhomogeneities is taken as the basis.

Following this optimization, a further optimization with respect to the bandwidth and the quality of the layer profile may be used if the square-wave subpulses are replaced by layer-selective subpulses with suitable properties, since the insensitivity to B₀ and B₁ inhomogeneities is not impaired in this connection. If various extreme cases are considered, compromises that allow improvements to be achieved even with regard to a plurality of quality targets are ultimately formed.

In a first extreme example, the demands on the SAR and the maximum output may be reduced by generating n subpulses with an amplitude that is lower by the factor 1/n. The pulse length is kept constant, so the time-bandwidth product (TBW) of the subpulses is reduced accordingly. This may lead to a deterioration in the quality of the layer profile, which for small flip angles <90° (each subpulse relates to just a portion of the total flip angle), may be optimized much more easily than for large flip angles. Thus, the layer profile adapted to the reduced flip angle of the subpulses may be optimized to partially or completely compensate the reduction in the time-bandwidth product depending on the choice of n. In the case of complete compensation, the bandwidth of the pulses may therefore be retained with the same pulse length (e.g., duration of the pulse) and reduced SAR or reduced maximum output.

Other cases exist. The optimization in the example described above may therefore also be changed such that the time-bandwidth product is retained, and the pulse length becomes greater, so the layer profile achieves the desired quality. In this case, the bandwidth of the layer selection, and therewith the spatial miscoding of off-resonant spins, is retained. The SAR and the maximum output are reduced, and the slice profile is improved.

If the time-bandwidth product and the pulse length are kept constant, then a significant reduction in the SAR and/or the maximum output may not be achieved, although the layer-selective bandwidth is significantly increased, and spatial excitation shifts of off-resonant spins are reduced.

Since the pulse length is a fundamental basis of the pulse optimization method, and the pulse optimization method is to be carried out again in the case of a change in the pulse length, the fundamental additional degree of freedom, which the present embodiments use, is the bandwidth (or, dependent thereon, the time-bandwidth product).

It is advantageous in the method of one embodiment if there is also an optimization in relation to the pulse length (e.g., with regard to energy parameters such as the SAR and/or the maximum output). The length of the single pulses may be optimized in the pulse optimization method with respect to at least one energy parameter, and the pulse length may be kept constant when determining the layer-selective subpulses. The energy parameter may be a parameter describing the local and/or global energy input in an object to be recorded and/or an energy parameter describing maximum output. This process is known from patent application DE 10 2011 006 151.7 discussed in the introduction. A variant that may be advantageously employed within the context of one embodiment is described therein. In one embodiment, the pulse optimization method may be run through several times iteratively. A current pulse length is stipulated to the pulse optimization method as being constant in the case of each iteration. Following a run-through of the pulse optimization method and with the aid of a criterion dependent on the current value of the energy parameter, whether the pulse length is adjusted again may be determined. The pulse optimization method is run through again. Within the scope of the present embodiments, the pulse length may be adjusted. The described criterion may also be a compromise condition, for example, as to whether layer-selective subpulses that provide a sufficiently good layer profile and/or a sufficiently good bandwidth may also be found with the present energy parameter (e.g., with regard to the maximum output (peak output).

A method thus results (e.g., by considering the pulse length) that may be used to reduce the SAR, to increase the bandwidth, to improve the layer profile and to reduce B₁ inhomogeneities. The bandwidth and the quality of the layer profile are improved. The increase in the bandwidth is advantageous if thick layers are to be excited for the three-dimensional imaging. The fat and water shift forces an increase in the field of view. This may be reduced by the method illustrated here. The signal outside of the layer may also be greatly reduced. This reduces artifacts due to folds. The method of one embodiment also provides similar advantages in the field of inner volume imaging.

Sync pulses may be used as layer-selective subpulses. Other conventional layer-selective subpulses may also be used.

A maximum amplitude of the layer-selective pulses is advantageously taken into account when determining the layer-selective subpulses. Such a limitation may be used, for example, due to a desired maximum output (peak output). If, for example, suitable subpulses that adhere to the desired boundary conditions and do not exceed the maximum amplitude at the same time are not provided, new square-wave subpulses may be determined and processed further in a re-parameterized run-through of the pulse optimization method (e.g., with regard to weighting parameters) when using requirements for the bandwidth and/or the profile quality in the case of an inability to fulfill the requirements when determining the layer-selective subpulses (e.g., on the basis of the maximum amplitude). An iterative implementation of the method may therefore also be carried out with respect to a criterion based on the peak output. By way of example, a maximum peak output of this kind may be anchored in the target function via weighting parameters. If the result of the pulse optimization method does not allow the requirements regarding the bandwidth and/or the profile quality to be fulfilled, then, for example, the weighting parameters may be increased in the target function in relation to the term based on the maximum output.

In addition to the described determining method, one embodiment also relates to a method for operating a magnetic resonance device having a plurality of high-frequency transmission coils including transmission channels configured for parallel transmission. An activation sequence is determined using the method, and the magnetic resonance device is operated according to the determined activation sequence. Description relating to the determining method of the present embodiments may be applied analogously to the operating method. To obtain a measurement report, the activation sequence is, for example, also supplemented by gradient pulses. When using a plurality of subpulses, as one embodiment proposes, the gradients of successive subpulses are connected so as to be opposed, so the regions to be excited are passed through several times in the K-space.

With regard to the determining method, almost the same requirements may be set for calculation of the activation sequence as in the known methods of the prior art. The target magnetization and therefore the magnetic resonance excitation quality requirement may be specified in the same way. For generating the activation sequence, a user of the determining method of the present embodiments may also specify a transmission K-space gradient trajectory (e.g., a gradient trajectory) that describes the locations in the K-space that are approached by adjustment of the individual gradients at certain times. The gradient trajectory determines at which spatial frequencies certain high-frequency energies are deposited.

Field maps that are recorded, for example, within the context of a calibration measurement may be specified as additional input data for the pulse optimization method. Such field maps (e.g., a B₀ map and B₁ maps) represent the homogeneity of the magnetic fields. One B₁ map, which may be recorded, for example, with a unified excitation, exists for each transmission channel.

In one embodiment, a magnetic resonance device including a controller configured for carrying out the methods of the present embodiments is provided. For example, the controller is configured to carry out one embodiment of the operating method, so a suitable activation sequence (and from this, a suitable measurement report) may be determined via the magnetic resonance device. The activation sequence may be used directly or may initially be kept available in a memory (e.g., for a plurality of measurements).

In another embodiment, a non-transitory computer-readable storage medium that stores instructions executable by one or more processors to determine the activation sequence for the magnetic resonance device, as described above, is provided. The instructions may be part of a computer program that may be loaded, for example, into the memory of a controller of the magnetic resonance device. The non-transitory computer-readable storage medium may, for example, be a storage medium such as a CD-ROM or another storage medium.

### BRIEF DESCRIPTION OF THE DRAWINGS

FIG. 1 shows a schematic diagram of one embodiment of a magnetic resonance device;

FIG. 2 illustrates the background of one embodiment of a method for determining an activation sequence for the magnetic resonance device;

FIG. 3 illustrates the background of one embodiment of a method for determining an activation sequence for the magnetic resonance device;

FIG. 4 illustrates the background of one embodiment of a method for determining an activation sequence for the magnetic resonance device; and

FIG. 5 shows a flowchart of one embodiment of a method for determining an activation sequence for the magnetic resonance device.

### DETAILED DESCRIPTION OF THE DRAWINGS

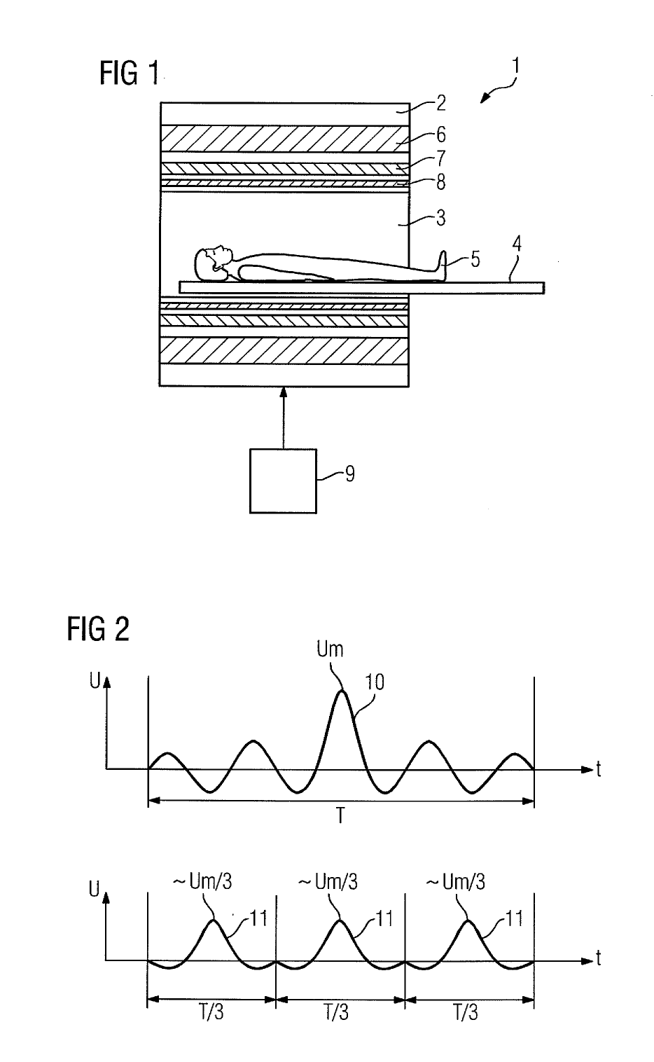

FIG. 1 shows a schematic diagram of one embodiment of a magnetic resonance device 1. The magnetic resonance device 1 includes a main magnetic unit 2 with a patient receptacle 3 located inside. An examination table 4 may be moved into the patient receptacle 3, so a patient 5 may be supported at a certain position inside the patient receptacle 3.

A basic field magnet 6, a gradient coil assembly 7 having magnetic field gradient coils and a whole body transmission coil 8 that may also be configured to receive magnetic resonance signals, are arranged in the main magnetic unit 2. Local coils that are to be arranged close to the patient 5 may also be provided, however, to receive the magnetic resonance signals.

The transmission coil 8 is configured for parallel transmission. Thus, the transmission coil 8 may be activated by way of a plurality of transmission channels, via which parallel single pulses of an activation sequence may be provided. The transmission coil 8 may be configured, for example, as a birdcage antenna. The transmission coil 8 then includes a number of antenna rods that extend parallel and extend so as to be equidistantly arranged in the longitudinal direction of the patient receptacle 3. At ends, the individual antenna rods are capacitively connected by an end ring. The antenna rods may accordingly be activated individually and may be allocated to one transmission channel, respectively.

To be able to execute magnetic resonance scans, the gradient coils of the gradient coil assembly 7 and the transmission coil 8 are activated with the aid of a measurement report that includes gradient pulses and high-frequency pulses (e.g., single pulses for the individual transmission channels of the transmission coil 8), therefore implementing parallel transmission (pTX). The single pulses for the various transmission channels may also be an activation sequence for the transmission coil 8 and may be determined by the magnetic resonance device 1. For this purpose, the magnetic resonance device 1 also includes a controller 9 that is configured to carry out the determining method and the operating method of one embodiment. The controller 9 is configured not only to bring about activation of the magnetic resonance device 1 for measurement data acquisition in accordance with a measurement report present in a memory of the controller 9 but to also determine this measurement report (e.g., the activation sequences). A sequence determining device (e.g., as part of the controller) may be provided. Alternatively, the function may be integrated into a different calculating device of the controller 9.

The exemplary embodiment of the method illustrated below allows a reduction in the specific absorption rate (SAR) at the same time as an increase in bandwidth, an improvement in the layer profile and a reduction in B₁ inhomogeneities without having to incur losses in relation to the insensitivity with regard to B₀-inhomogeneities in the process. For this purpose, composite pulses are used. Each single pulse allocated to a transmission channel is thus divided into subpulses. The degrees of freedom, provided as a result, for optimization with regard to an ideal compromise are taken into account, and this is explained in greater detail below with regard to FIGS. 2-4.

FIGS. 2-4 illustrate which optimization options result from using composite pulses. How these optimization options are used within the scope of the method is described below.

In the upper part, FIG. 2 shows an overall pulse 10 that is divided into subpulses 11 shown in the lower region. The pulse length (e.g., the duration of the overall pulse 10) is designated T, and the maximum amplitude is designated Uₘ. According to FIG. 2, three subpulses 11 have been produced that each have a pulse length of T/3 and an amplitude of Uₘ/3. The pulse length T of the overall pulse is therefore obtained, the time-bandwidth product of the subpulses 11 is reduced accordingly, and this may lead to a deterioration in the layer profile. Each of the subpulses 11 also produces a smaller flip angle, for which the layer profile may be optimized much more easily than for large flip angles. An optimization of the layer profile adapted to the reduced flip angle of the subpulses 11 may therefore partially or completely compensate the shorter pulse length of the subpulses 11 depending on the choice of the number of subpulses. The bandwidth is retained with identical total duration T and reduced SAR or reduced peak output.

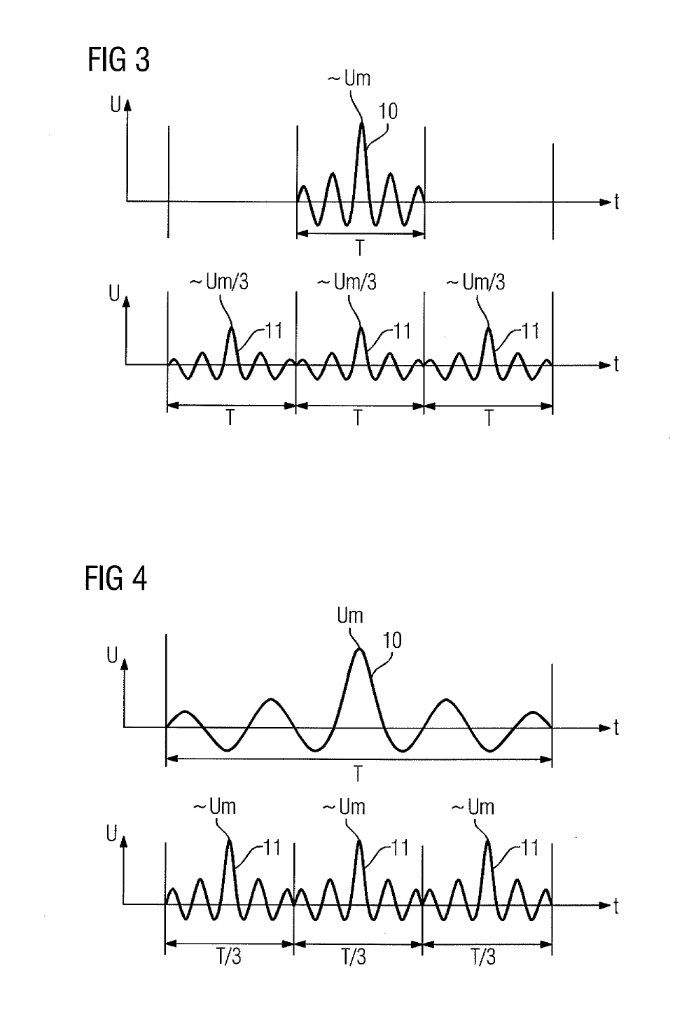

FIG. 3 shows a further possibility for dividing an overall pulse 10 into subpulses 11. The time-bandwidth product is obtained, for example, where the length of each subpulse 11 is accordingly also T. This provides that the quality of the layer profile improves, while the bandwidth of the layer selection and the spatial miscoding of off-resonant spins are retained thereby. Once the amplitude is reduced to one third again, the SAR and the peak output are reduced, and the slice profile is improved.

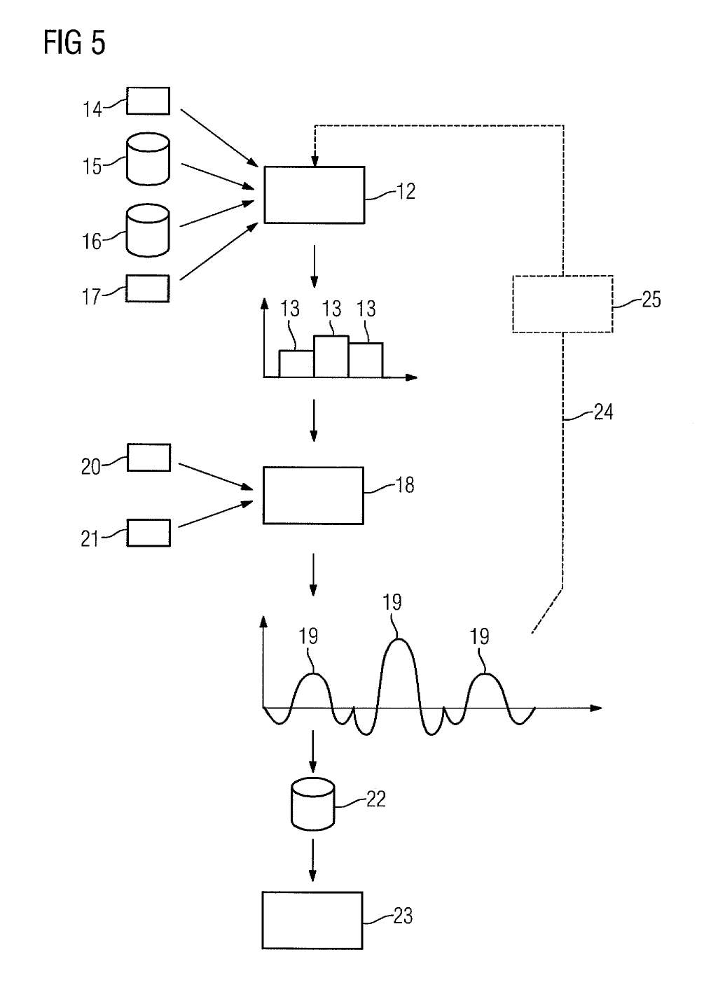

In the embodiment illustrated in FIG. 4, both the time-bandwidth product and the pulse length are obtained, so a significant reduction in the SAR or peak output may not be achieved. However, the layer-selective bandwidth is significantly increased, so spatial excitation shifts of off-resonant spins are reduced.

In one embodiment, the optimization criteria of the described cases are combined as desired to obtain the best compromise from all parameters for the respective application.

In this regard, FIG. 5 shows the basic progression of one embodiment of the operating method that includes one embodiment of the determining method. In act 12, a pulse optimization method is used for determining composite pulses that provide a certain number of square-wave subpulses 13 (e.g., three square-wave subpulses) as a result. Other numbers of subpulses may be provided. The pulse optimization method receives various inputs and works towards various aims. Therefore, a magnetic resonance excitation quality requirement 14, as may be known, describing a target magnetization is used as an input parameter, and a B₀ map 15 and B₁ maps 16 are supplied as well. In the exemplary embodiment described, the pulse length is also considered as an additional parameter to be optimized. An energy parameter to be optimized (e.g., an SAR value) is added in the target function. This additional target requirement is denoted by the box 17 in FIG. 5. The specific procedure with this expansion of the pulse optimization method is described by way of example in application DE 10 2011 006 151.7. In another embodiment of the method, the pulse length may, however, also be determined by iterative run-throughs of the pulse optimization method with the aid of a criterion containing the energy parameter.

After the optimization act 12, the square-wave subpulses 13 obtained are replaced in act 18 by layer-selective subpulses 19 (e.g., gauss-sync pulses), with the pulse length, pulse integral (e.g., flip angle), and the phase of the square-wave pulses 13 are retained. Optimization aims in act 18 are indicated, for example, by boxes 20 and 21, the quality of the profile of the layer to be excited, and the bandwidth. The associated gradient pulses are also already determined in act 18.

An overall measurement report 22 is determined, for example, by the controller 9 of the magnetic resonance device 1. The overall measurement report 22 may be stored and may be used thereafter (act 23) to activate the magnetic resonance device 1 to record magnetic resonance images.

The optimization requirements for the bandwidth and the quality of the layer profile may also include limits. Such requirements for the bandwidth and the profile quality may not be achieved with some of the pulse optimization method results obtained, for example, if a maximum output and therefore a maximum amplitude has to be exceeded for this purpose. If such an inability to achieve requirements exists, then according to the broken-line arrow 24, with a change in the parameters of the pulse optimization method in act 25 (e.g., the weighting parameters), the pulse optimization method is run through again in act 12 with changed conditions to still fulfill the requirements.

Such an iterative procedure may be used in an embodiment, in which the pulse length is not optimized within the context of the pulse optimization method. Instead, a fixed pulse length is specified, and the fixed pulse length may be suitably changed with the aid of at least one criterion to produce a type of iterativity. For example, in one embodiment of the method, the iterative procedure as a whole may be selected with the aid of the variables or aims to be optimized, so a suitable compromise may be found.

Although the invention has been illustrated and described in more detail with reference to the above-described embodiment, the invention is not limited by the disclosed examples, and other variations may be derived herefrom by a person skilled in the art without departing from the scope of the invention.

While the present invention has been described above by reference to various embodiments, it should be understood that many changes and modifications can be made to the described embodiments. It is therefore intended that the foregoing description be regarded as illustrative rather than limiting, and that it be understood that all equivalents and/or combinations of embodiments are intended to be included in this description.

1. A method for determining an activation sequence for a magnetic resonance device, the activation sequence comprising single pulses to be emitted simultaneously for a plurality of individually activatable high-frequency transmission channels, the method comprising:
determining an amplitude and a phase of a plurality of square-wave subpulses, of which the single pulse is composed, for a predefined target magnetization for each of the single pulses; and
determining optimized, layer-selective subpulses for each square-wave subpulse of the plurality of square-wave subpulses while retaining phase and integral of the square-wave subpulse with regard to a bandwidth of the plurality of square-wave subpulses, a quality of a profile of a layer to be excited, or a combination thereof.

2. The method as claimed in claim 1, wherein sync-pulses are used as the layer-selective subpulses.

3. The method as claimed in claim 1, wherein determining the optimized, layer-selective subpulses comprises taking a maximum amplitude of the optimized, layer-selective subpulses into account.

4. The method as claimed in claim 3, wherein when using requirements for the bandwidth, the profile quality, or the combination thereof in the case of an inability to fulfill the requirements when determining the optimized, layer-selective subpulses on the basis of the maximum amplitude, new square-wave subpulses are determined and processed further in a re-parameterized run-through of the determining of the amplitude and the phase of the plurality of square-wave subpulses with regard to weighting parameters,.

5. The method as claimed in claim 1, further comprising optimizing the length of the single pulses with respect to at least one energy parameter,
wherein the pulse length is kept constant when determining the optimized, layer-selective subpulses.

6. The method as claimed in claim 5, wherein the optimizing comprises optimizing the length of the single pulses with respect to an energy parameter describing a local energy input, a global energy input, or the local energy input and the global energy input into an object to be recorded, a maximum output, or a combination thereof.

7. The method as claimed in claim 2, wherein determining the optimized, layer-selective subpulses comprises taking a maximum amplitude of the optimized, layer-selective subpulses into account.

8. The method as claimed in claim 2, further comprising optimizing the length of the single pulses with respect to at least one energy parameter,
wherein the pulse length is kept constant when determining the optimized, layer-selective subpulses.

9. The method as claimed in claim 3, further comprising optimizing the length of the single pulses with respect to at least one energy parameter,
wherein the pulse length is kept constant when determining the optimized, layer-selective subpulses.

10. The method as claimed in claim 4, further comprising optimizing the length of the single pulses with respect to at least one energy parameter,
wherein the pulse length is kept constant when determining the optimized, layer-selective subpulses.

11. A method for operating a magnetic resonance device having high-frequency transmission coils comprising a plurality of transmission channels configured for simultaneous emission, the method comprising:
determining an activation sequence comprising single pulses to be emitted simultaneously for the plurality of transmission channels, the plurality of transmission channels being individually activatable high-frequency transmission channels, the determining comprising:
determining an amplitude and a phase of a plurality of square-wave subpulses, of which the single pulse is composed, for a predefined target magnetization for each of the single pulses; and
determining optimized, layer-selective subpulses for each square-wave subpulse of the plurality of square-wave subpulses while retaining phase and integral of the square-wave subpulse with regard to a bandwidth of the plurality of square-wave subpulses, a quality of a profile of a layer to be excited, or a combination thereof; and
operating the magnetic resonance device according to the determined activation sequence.

12. A magnetic resonance device comprising:
a controller configured to determine an activation sequence for a magnetic resonance device, the activation sequence comprising single pulses to be emitted simultaneously for a plurality of individually activatable high-frequency transmission channels, the controller being further configured to:
determine an amplitude and a phase of a plurality of square-wave subpulses, of which the single pulse is composed, for a predefined target magnetization for each of the single pulses; and
determine optimized, layer-selective subpulses for each square-wave subpulse of the plurality of square-wave subpulses while retaining phase and integral of the square-wave subpulse with regard to a bandwidth of the plurality of square-wave subpulses, a quality of a profile of a layer to be excited, or a combination thereof.

13. In a non-transitory computer-readable storage medium that stores instructions executable by one or more processors to determine an activation sequence for a magnetic resonance device, the activation sequence comprising single pulses to be emitted simultaneously for a plurality of individually activatable high-frequency transmission channels, the instructions comprising:
determining an amplitude and a phase of a plurality of square-wave subpulses, of which the single pulse is composed, for a predefined target magnetization for each of the single pulses; and
determining optimized, layer-selective subpulses for each square-wave subpulse of the plurality of square-wave subpulses while retaining phase and integral of the square-wave subpulse with regard to a bandwidth of the plurality of square-wave subpulses, a quality of a profile of a layer to be excited, or a combination thereof.
